(19) United States
(12) Patent Application Publication
(10) Pub. No.: US 2009/0205854 A1
(43) Pub. Date: Aug. 20, 2009

(54) Printed circuit board for a package and manufacturing method thereof

(75) Inventors: Dong-Gyu Lee, Suwon-si (KR); Jin-Won Choi, Seoul (KR); Ki-Young Yoo, Suwon-si (KR); Tae-Joon Chung, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/219,140

(22) Filed: Jul. 16, 2008

(30) Foreign Application Priority Data
Feb. 15, 2008 (KR) 10-2008-0013912

(51) Int. Cl. H05K 1/09; H05K 3/00

(52) U.S. Cl. 174/257; 29/843

(57) ABSTRACT

A printed circuit board for use in a package and to a method of manufacturing the printed circuit board. The method of manufacturing the printed circuit board can include: providing a substrate, on one side of which at least one solder pad and at least one guide pad are formed; forming a solder resist layer over the one side of the substrate; uncovering at least one portion of the solder resist layer such that the guide pad is exposed; applying a surface treatment on the exposed guide pad; uncovering at least one portion of the solder resist layer such that the solder pad is exposed; and forming a solder bump on the exposed solder pad. With this method, the amount of surface treatment applied can be minimized, for reduced costs, and the occurrence of undiffused layers can be avoided, for improved reliability in the final product.

### CROSS-REFERENCE TO RELATED APPLICATIONS

This application claims the benefit of Korean Patent Application No. 10-2008-0013912 filed with the Korean Intellectual Property Office on Feb. 15, 2008, the disclosure of which is incorporated herein by reference in its entirety.

### BACKGROUND

1. Technical Field

The present invention relates to a printed circuit board for use in a package and to a method of manufacturing the printed circuit board.

2. Description of the Related Art

In accordance with rapid advances in semiconductor IC's, there is a need also for advances and improvements in packages that connect a chip and CPU with a PCB (printed circuit board). The existing wire bonding technology has been found to be limited in implementing the ultra-fine pitch in current circuits and patterns.

As an alternative to wire bonding, the flip chip substrate using solder bumps and screen printing technology has been researched and commercialized, but this too may be limited in implementing current fine-line patterns, which are being produced in smaller and smaller sizes.

Ultimately, a method other than screen printing is needed for providing a pattern having ultra-fine pitch. One such method is to use plating technology. Forming the solder bumps by plating makes it possible to implement ultra-fine patterns, while providing the added benefits of preventing voids and preventing defects caused by external factors.

FIG. 1 through FIG. 10 are cross sectional views representing a method of manufacturing a printed circuit board for a package according to the related art. A method of manufacturing a printed circuit board according to the related art will be described as follows with reference to FIGS. 1 to 10.

First, on the substrate of the outermost layer, solder pads 2 may be formed, over which bumps can be positioned, and guide pads 3 may be formed, which can act as reference points for reliability testing equipment. Then, a solder resist ink 1 may be coated, as illustrated in FIG. 1.

Then, all of the guide pads 3 and solder pads 2 may be uncovered using an imaging process, as illustrated in FIG. 2. A surface treatment may then be applied using an electroless-deposited nickel (Ni) layer and an electroless-deposited gold (Au) layer or using electroless-deposited nickel (Ni), palladium (Pd); and gold (Au) layers. FIG. 3 illustrates an example in which a nickel plating layer 4 and a gold plating layer 5 are formed.

Afterwards, a seed layer 6 may be formed over the entire substrate using a sputtering process, as illustrated in FIG. 4, and a photosensitive dry film 7′ may be stacked, illustrated in FIG. 5. A plating resist layer 7 may then be formed, as illustrated in FIG. 6, in which only the portions above the solder pads 2 where solder is to be plated are uncovered, using exposure and development processes.

Then, electroless plating may be performed in the portions above the uncovered solder pads 2 to form a solder plating layer 8 of a desired thickness, as illustrated in FIG. 7. Afterwards, the plating resist layer 7 may be removed, as illustrated in FIG. 8, and the seed layer 6 may be removed, as illustrated in FIG. 9.

Finally, a flux may be coated over the plated solder, and a reflow process may be performed, to form round solder bumps 9 as illustrated in FIG. 10.

As described above, when manufacturing a printed circuit board for a package according to a method based on the related art, a surface treatment layer may be formed over the solder pads where solder bumps are to be formed, examples of which include “ENIG,” which is to form an “electroless nickel and immersion gold” layer, and “ENEPIG,” which is to form an “electroless nickel, electroless palladium, and immersion gold” layer.

The outermost layer of such surface treatment layer should be diffused through and out of the solder, during the reflow process, and consequently removed. However, there may be occurrences in which the outermost layer is not sufficiently diffused, due to the method of surface treatment or the thickness of the surface treatment layer, so that a desired intermetallic compound may not be formed between the solder and the pad. The undiffused layer and the abnormal intermetallic metal compound may cause partial delamination, and may consequently decrease the adhesion between the solder and the solder pad. This can greatly lower the reliability of the final product.

### SUMMARY

An aspect of the invention provides a printed circuit board for use in a package, and a method of manufacturing the printed circuit board, in which the occurrence of an undiffused layer can be avoided to improve the reliability of the product, and in which the occurrence of voids in the solder bumps can be prevented.

Another aspect of the invention provides a method of manufacturing a printed circuit board for use in a package that includes: providing a substrate, on one side of which at least one solder pad and at least one guide pad are formed; forming a solder resist layer over the one side of the substrate; uncovering at least one portion of the solder resist layer such that the guide pad is exposed; applying a surface treatment on the exposed guide pad; uncovering at least one portion of the solder resist layer such that the solder pad is exposed; and forming a solder bump over the exposed solder pad.

In certain embodiments, forming the solder bump can be performed by: forming a seed layer over the one side of the substrate; forming a plating resist layer, in which at least one opening corresponding with the solder pad is formed, over the one side of the substrate; plating a solder over the solder pad by electroplating; removing the plating resist layer; applying flash etching such that exposed portions of the seed layer are removed; and reflowing the plated solder.

Also, the surface treatment applied on the guide pad can be performed by forming a coating layer made of gold, silver, tin, or an organic solderability preservative (OSP) directly over the guide pad. The operation of uncovering at least one portion of the solder resist layer such that the solder pad is exposed may be performed using laser direct ablation (LDA) technology.

Yet another aspect of the invention provides a printed circuit board for a package that includes: a substrate; a solder pad and a guide pad formed on one side of the substrate; a solder resist layer, which covers the one side of the substrate, and in which openings corresponding with the solder pad and the guide pad are formed; a coating layer, which is formed directly over the guide pad, and which is made of gold, silver, tin, or an organic solderability preservative (OSP); and a solder bump formed directly over the solder pad.

Additional aspects and advantages of the present invention will be set forth in part in the description which follows, and in part will be obvious from the description, or may be learned by practice of the invention.

### BRIEF DESCRIPTION OF THE DRAWINGS

FIG. 1, FIG. 2, FIG. 3, FIG. 4, FIG. 5, FIG. 6, FIG. 7, FIG. 8, FIG. 9, and FIG. 10 are cross sectional views representing a method of manufacturing a printed circuit board for a package according to the related art.

FIG. 11 is a flowchart illustrating a method of manufacturing a printed circuit board for a package according to an embodiment of the invention.

FIG. 12, FIG. 13, FIG. 14, FIG. 15, FIG. 16, FIG. 17, FIG. 18, FIG. 19, FIG. 20, FIG. 21, and FIG. 22 are cross sectional views representing the method of manufacturing a printed circuit board for a package illustrated in FIG. 11.

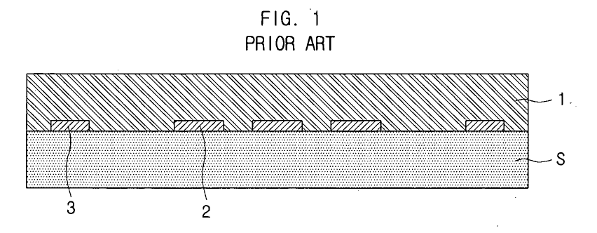

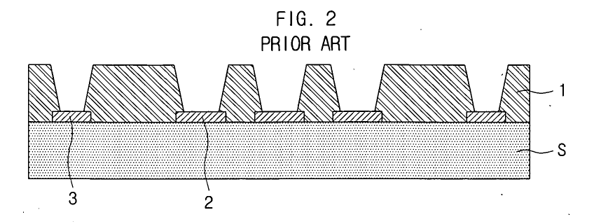

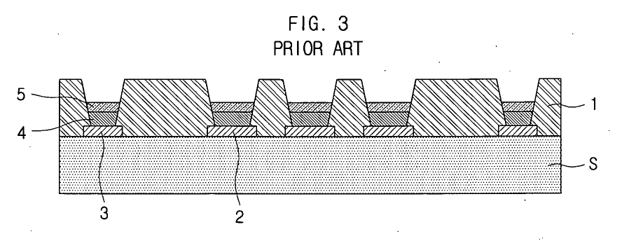

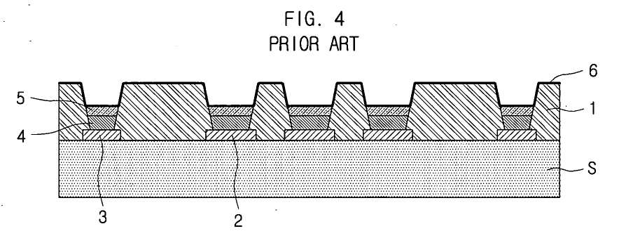

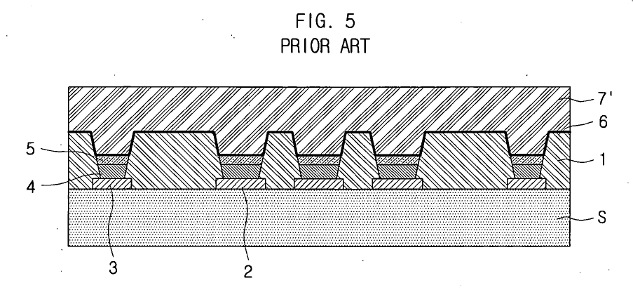

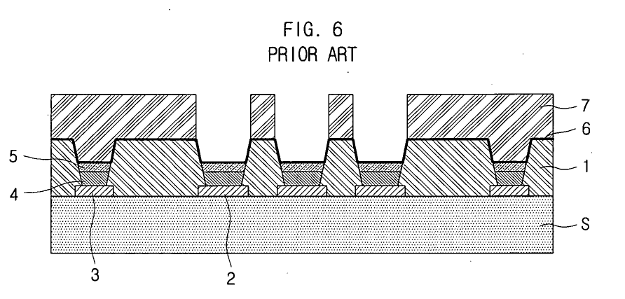

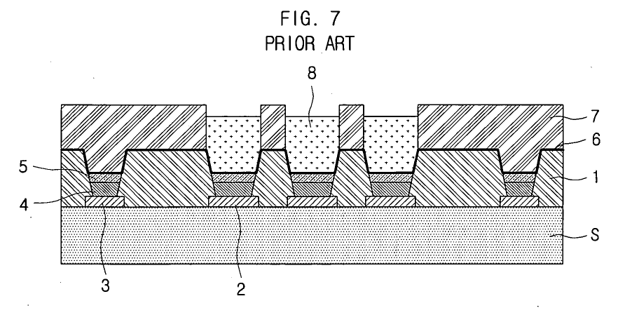

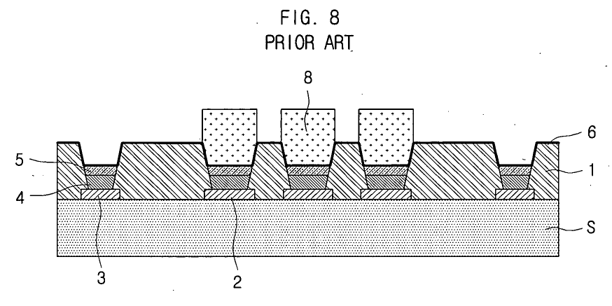

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various elements, such elements must not be limited to the above terms. The above terms are used only to distinguish one element from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The printed circuit board for use in a package and the method of manufacturing the printed circuit board according to certain embodiments of the invention will be described below in more detail with reference to the accompanying drawings. Those elements that are the same or are in correspondence are rendered the same reference numeral regardless of the figure number, and redundant explanations are omitted.

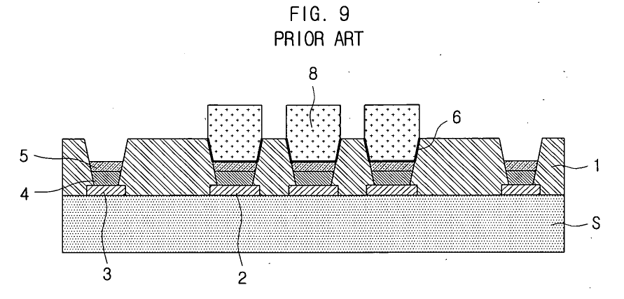

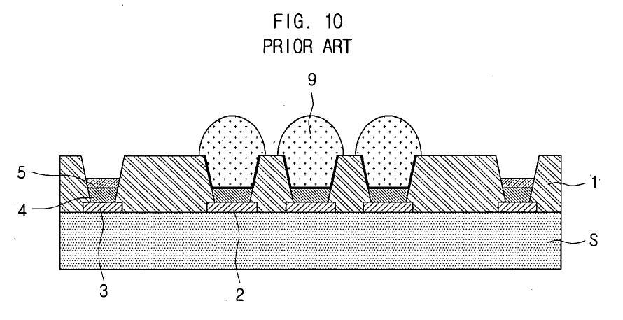

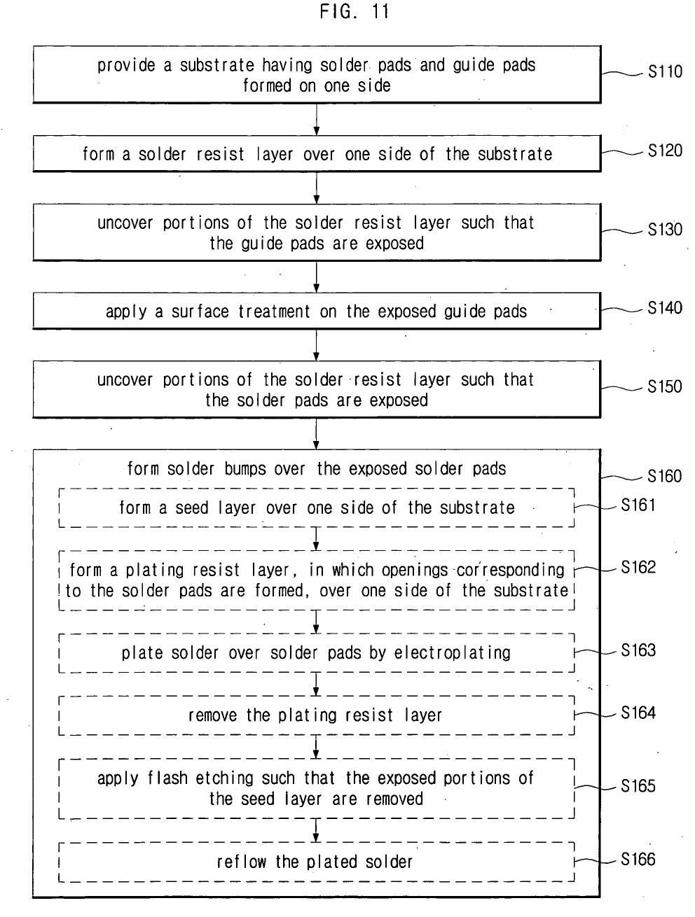

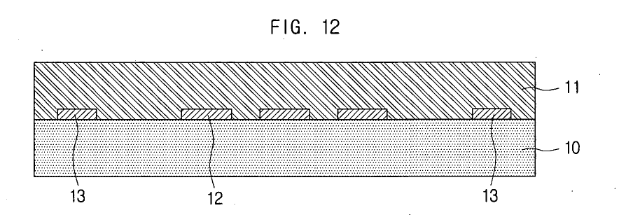

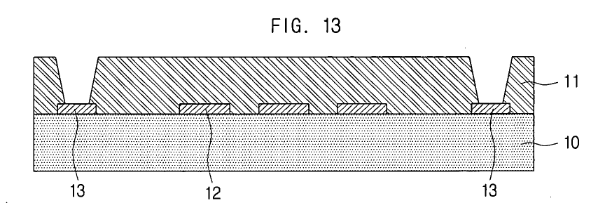

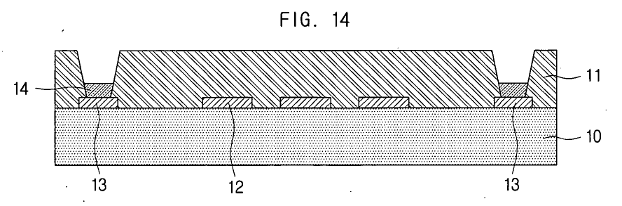

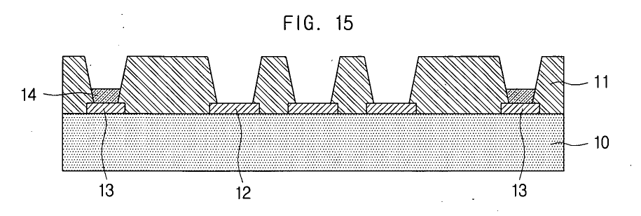

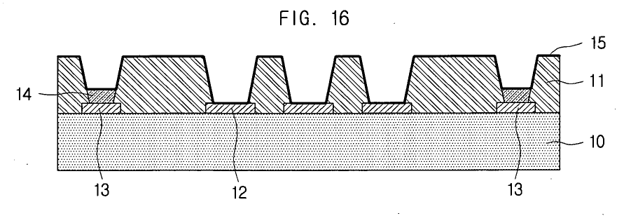

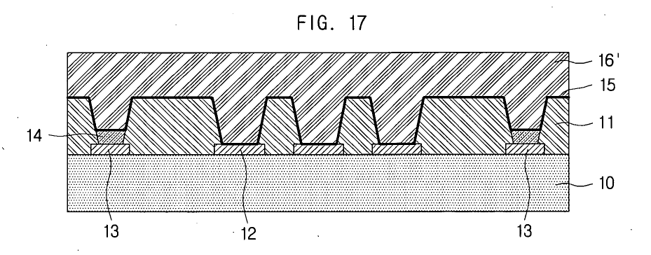

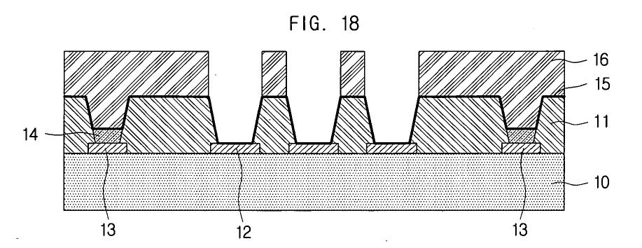

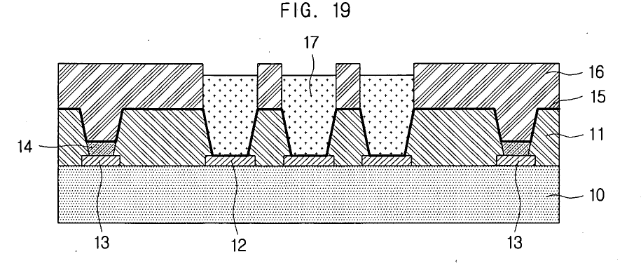

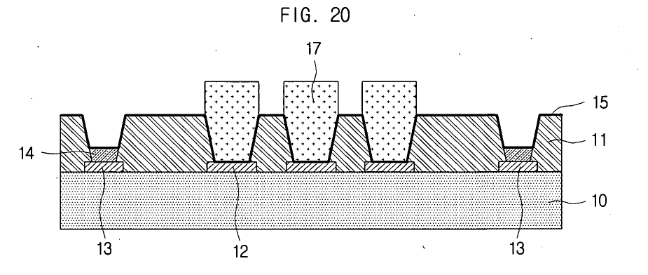

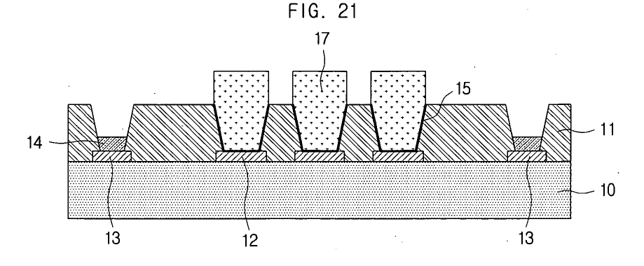

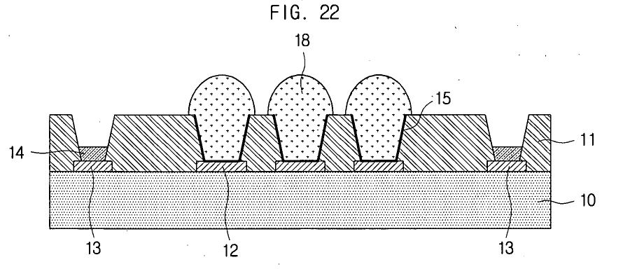

FIG. 11 is a flowchart illustrating a method of manufacturing a printed circuit board for a package according to an embodiment of the invention, and FIG. 12 through FIG. 22 are cross sectional views representing the method of manufacturing a printed circuit board for a package illustrated in FIG. 11. In FIGS. 12 to 22, there are illustrated a substrate 10, a solder resist layer 11, solder pads 12, guide pads 13, a coating layer 14, a seed layer 15, a plating resist layer 16, a solder plating layer 17, and solder bumps 18.

First, as illustrated in FIG. 12, a substrate 10 having solder pads 12 and guide pads 13 formed on one side can be prepared (S110), and a solder resist layer 11 can be formed over one side of the substrate 10 (S120). The solder pads 12 can be where solder bumps 18 (see FIG. 22) may be formed. The solder bumps 18 (see FIG. 22) may serve to electrically connect a circuit pattern (not shown), etc., formed on the substrate 10 with an electrical component, etc. The guide pads 13 may serve as reference points in reliability tests, etc., for the product.

Next, as illustrated in FIG. 13, portions of the solder resist layer 11 can be uncovered in such a way that the guide pads 13 are exposed (S130), and then, as illustrated in FIG. 14, a surface treatment can be applied to the exposed guide pads 13 (S140). That is, the surface treatment process can be performed after exposing only the guide pads 13, in order that the surface treatment may be applied only to the guide pads 13.

Since the surface treatment may be applied on only the guide pads 13 and not on the solder pads 12 where the solder bumps 18 (see FIG. 22) are to be formed, an undiffused layer may not exist between the solder bumps 18 and solder pads 12, whereby the bonding between the solder bumps 18 and solder pads 12 may be performed with a certain level of reliability.

In this particular embodiment, a method of directly removing the solder resist layer 11 by laser direct ablation (LDA) can be used for uncovering the portions of the solder resist layer 11 such that the guide pads 13 are exposed. LDA technology makes it possible to implement selective openings for the guide pads 13 more easily. Of course, other methods may also be used besides LDA, such as those employing exposure and development processes.

Although the surface treatment process for the guide pads 13 can include sequentially performing nickel plating and gold plating, this particular embodiment utilizes a method of direct gold plating, assuming that the guide pads 13 will be used only for recognition by optical devices, etc. Gold plating, as well as silver plating, tin plating, or forming an organic solderability preservative (OSP), etc., can be used to form a coating layer 14 directly over the guide pads 13.

Then, as illustrated in FIG. 15, portions of the solder resist layer 11 can be uncovered in such a way that the solder pads 12 are exposed (S150), and solder bumps 18 (see FIG. 22) can be formed over the exposed solder pads 12 (S160). LDA can be employed in uncovering portions of the solder resist to expose the solder pads 12, as already described above. A method of forming the solder bumps 18 over the exposed solder pads 12 will be described in more detail as follows.

First, as illustrated in FIG. 16, a metal seed layer 15 can be formed over one side of the substrate 10 (S161), to serve as an electrode for electroplating. The seed layer 15 can be formed to a thickness of 0.2 to 1 μm using the same material as that of the solder pads 12, and can be formed by a sputtering method or an electroless plating method, etc. Thus, if the solder pads 12 are made of a copper material, the seed layer 15 can be formed using copper. The thickness and forming method of the seed layer 15 presented here are merely examples, and can be varied according to manufacturing requirements.

After thus forming the seed layer 15, a plating resist layer 16, in which openings corresponding with the solder pads 12 are formed, can be formed over one side of the substrate 10 (S162), and solder can be plated over the solder pads 12 by electroplating (S163).

This can be achieved by a method of stacking a photosensitive dry film 16′ over the seed layer 15, as illustrated in FIG. 17, uncovering the solder pads 12 using exposure and development processes, as illustrated in FIG. 18, and forming a solder plating layer 17 by performing electroplating, as illustrated in FIG. 19.

Afterwards, the plating resist layer 16 can be removed (S164), as illustrated in FIG. 20, and flash etching can be performed to remove the exposed portions of the seed layer 15 (S165), as illustrated in FIG. 21, and reflowing can be performed for the solder plating layer 17 (S166), to form round solder bumps 18 such as those illustrated in FIG. 22.

A printed circuit board for a package according to another aspect of the invention will now be described with reference to FIG. 22. As in the example illustrated in FIG. 22, a printed circuit board for use in a package based on this embodiment can be composed mainly of a substrate 10; solder pads 12 and guide pads 13 formed on one side of the substrate 10; a solder resist layer 11, which covers one side of the substrate 10, and in which openings corresponding with the solder pads 12 and guide pads 13 are formed; a coating layer 14, which is formed directly over the guide pads 13, and which is made of gold, silver, tin, or an organic solderability preservative; and solder bumps 18 formed directly over the solder pads 12.

Here, to describe the solder bumps 18 as being formed directly over the solder pads 12 is intended to convey the meaning that there is no different material interposed between the solder bumps 18 and the solder pads 12, and is not intended to mean that not even the seed layer 15 (see FIG. 21) made of the same material as the solder pads 12, or an alloy layer (not shown) between the solder bumps 18 and the seed layer 15 or between the solder bumps 18 and the solder pads 12, may be formed.

This printed circuit board for use in a package can be manufactured by substantially the same or a similar method as that of the previously described embodiment.

The printed circuit board for use in a package according to this embodiment does not include a separate surface treatment between the solder pads 12 and the solder bumps 18, and therefore does not include an undiffused layer. Also, as a coating layer 14 made of gold, silver, tin, or an organic solderability preservative can be formed directly over the guide pads 13, material costs can be reduced, and the manufacturing process can be simplified.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention. Many embodiments other than those set forth above can be found in the appended claims.

What is claimed is:

1. A method of manufacturing a printed circuit board for use in a package, the method comprising:
providing a substrate, the substrate having at least one solder pad and at least one guide pad formed on one side thereof;
forming a solder resist layer over the one side of the substrate;
uncovering at least one portion of the solder resist layer such that the guide pad is exposed;
applying a surface treatment on the exposed guide pad;
uncovering at least one portion of the solder resist layer such that the solder pad is exposed; and
forming a solder bump over the exposed solder pad.

2. The method of claim 1, wherein the forming of the solder bump comprises:
forming a seed layer over the one side of the substrate;
forming a plating resist layer over the one side of the substrate, the plating resist layer having at least one opening formed therein, the opening corresponding with the solder pad;
plating a solder over the solder pad by electroplating;
removing the plating resist layer;
applying flash etching such that exposed portions of the seed layer are removed; and
reflowing the plated solder.

3. The method of claim 1, wherein the applying of the surface treatment is performed by forming a coating layer directly over the guide pad, the coating layer made of gold, silver, tin, or an organic solderability preservative (OSP).

4. The method of claim 1, wherein the uncovering of at least one portion of the solder resist layer such that the solder pad is exposed is performed using laser direct ablation (LDA).

5. A printed circuit board for a package, the printed circuit board comprising:
a substrate;
a solder pad and a guide pad formed on one side of the substrate;
a solder resist layer covering the one side of the substrate and having openings formed therein, the openings corresponding with the solder pad and the guide pad;
a coating layer formed directly over the guide pad and made of gold, silver, tin, or an organic solderability preservative (OSP); and
a solder bump formed directly over the solder pad.
